(19) United States
(12) Patent Application Publication
(10) Pub. No.: US 2025/0123336 A1
(43) Pub. Date: Apr. 17, 2025

(54) BATTERY MONITORING SYSTEM, BATTERY MONITORING DEVICE, AND BATTERY MONITORING METHOD

(71) Applicants: DENSO TEN Limited, Kobe-shi, Hyogo (JP); DENSO CORPORATION, Kariya-shi, Aichi (JP)

(72) Inventors: Ryuusuke MIYAKE, Kobe (JP); Tatsuhiro NUMATA, Kariya (JP); Takeshi IIDA, Kariya (JP)

(73) Assignees: DENSO TEN Limited, Kobe-shi, Hyogo (JP); DENSO CORPORATION, Kariya-shi, Aichi (JP)

(21) Appl. No.: 18/688,624

(22) PCT Filed: Sep. 2, 2022
(86) PCT No.: PCT/JP2022/033097

§ 371 Date: Mar. 1, 2024

(30) Foreign Application Priority Data
Nov. 24, 2021 (JP) 2021-190208

(51) Int. Cl. G01R 31/396; G01R 31/3842

(52) U.S. Cl. CPC G01R 31/396; G01R 31/3842

(57) ABSTRACT

A battery monitoring system includes battery measuring devices and a battery monitoring device. Each of the battery measuring devices detects voltage information on a corresponding battery. The battery monitoring device is configured to: acquire the voltage information from each of the battery measuring devices by using wireless communication; and acquire current information on current flowing through the corresponding battery from an electric-current sensor. The battery monitoring device includes a control unit and a wireless communication unit. The wireless communication unit executes wireless communication with the battery measuring devices with a predetermined period. The control unit is configured to: cause the wireless communication unit to output a voltage measuring instruction; and based on a timing at which the wireless communication unit transmits the voltage measuring instruction to the battery measuring device, acquire the current information during a time interval in which the battery measuring device acquires voltage information.

### FIELD

The embodiments discussed herein are directed to a battery monitoring system, a battery monitoring device, and a battery monitoring method.

### BACKGROUND

In order to calculate a cell resistance of a battery, information on voltages and currents that are acquired at the same acquisition timing is necessary. Additionally, a recent battery monitoring device executes wireless communication with a battery measuring device caused by employment of a harnessless configuration. For example, in a battery monitoring system disclosed in Patent Literature 1, a plurality of battery measuring devices provided in respective batteries measures synchronized voltages and currents of the batteries, and transmits the measured voltages and currents to a battery monitoring device by using wireless communication.

### CITATION LIST

### Patent Literature

Japanese Laid-open Patent Publication No. 2021-068611

### SUMMARY

### Technical Problem

However, in the battery monitoring system disclosed in Patent Literature 1, each battery measuring device and a corresponding electric-current sensor is necessary to be connected by using a harness, and thus the number of harnesses increases as the number of battery measuring devices increases, thereby leading to disturbance to realization of a harnessless configuration.

Thus, from a viewpoint of realization of a harnessless configuration, it is desirable that a battery monitoring device transmits, to each of battery measuring devices, a corresponding voltage measuring instruction by using wireless communication, acquires voltage information on batteries from the battery measuring devices, and acquires current information on the batteries at an acquisition timing that is synchronized with an acquisition timing of the voltage information.

Note that in wireless communication, an error may occur in a communication timing compared with wired communication. Thus, a battery monitoring device is not capable of recognizing a precise acquisition timing of voltage information by a battery measuring device, and further is not capable of acquiring current information on the battery at an acquisition timing that is synchronized with the acquisition timing of the voltage information by the battery measuring device, in some cases.

One aspect of the embodiments is made in view of the aforementioned, and an object of the embodiments is to provide a battery monitoring system, a battery monitoring device, and a battery monitoring method capable of acquiring current information on a battery at an acquisition timing that is synchronized with an acquisition timing of voltage information obtained by a battery measuring device.

### Solution to Problem

A battery monitoring system according to one aspect of embodiments includes a battery measuring device and a battery monitoring devices. The battery measuring device detects voltage information on a battery. The battery monitoring device is configured to: acquire the voltage information from the battery measuring device by using wireless communication; and acquire current information on current flowing through the battery from an electric-current sensor. The battery monitoring device includes a control unit and a wireless communication unit. The wireless communication unit executes wireless communication with the battery measuring device with a predetermined period. The control unit is configured to: cause the wireless communication unit to output a voltage measuring instruction; and based on a timing at which the wireless communication unit transmits the voltage measuring instruction to the battery measuring device, acquire the current information during a time interval in which the battery measuring device acquires voltage information.

### Advantageous Effects of Invention

In accordance with a battery monitoring system, a battery monitoring device, and a battery monitoring method according to one aspect of embodiments, it is possible to acquire current information on batteries at an acquisition timing that is synchronized with an acquisition timing of voltage information by a battery measuring device.

### BRIEF DESCRIPTION OF DRAWINGS

FIG. 1 is a diagram illustrating a battery monitoring system using wired communication.

FIG. 2 is a diagram illustrating a battery monitoring system according to a first embodiment.

FIG. 3 is a diagram illustrating a connection interval of a wireless communication unit according to the first embodiment.

FIG. 4 is a timing diagram illustrating an operation example of the battery monitoring system according to the first embodiment.

FIG. 5 is a flowchart illustrating one example of a process executed by a control unit according to the first embodiment.

FIG. 6 is a diagram illustrating a battery monitoring system according to a second embodiment.

FIG. 7 is a timing diagram illustrating an operation example of the battery monitoring system according to the second embodiment.

FIG. 8 is a flowchart illustrating one example of a process executed by a control unit according to the second embodiment.

FIG. 9 is a flowchart illustrating one example of a process executed by a battery measuring device according to the second embodiment.

### Description of Embodiments

Hereinafter, exemplary embodiments of a battery monitoring system, a battery monitoring device, and a battery monitoring method disclosed in the present application will be described in detail with reference to the accompanying drawings. In addition, the illustrative embodiments disclosed below are not intended to limit the present invention. A battery monitoring system according to the embodiments is a system that monitors a state of a lithium-ion battery for driving a vehicle, which is provided in an electric automobile or a hybrid vehicle, for example.

The battery monitoring system may be configured to monitor a state of an arbitrary battery other than a battery for vehicle. Hereinafter, a battery monitoring system using wired communication will be explained, and then a battery monitoring system using wireless communication according to the embodiments will be explained.

### 1. Battery Monitoring System Using Wired Communication

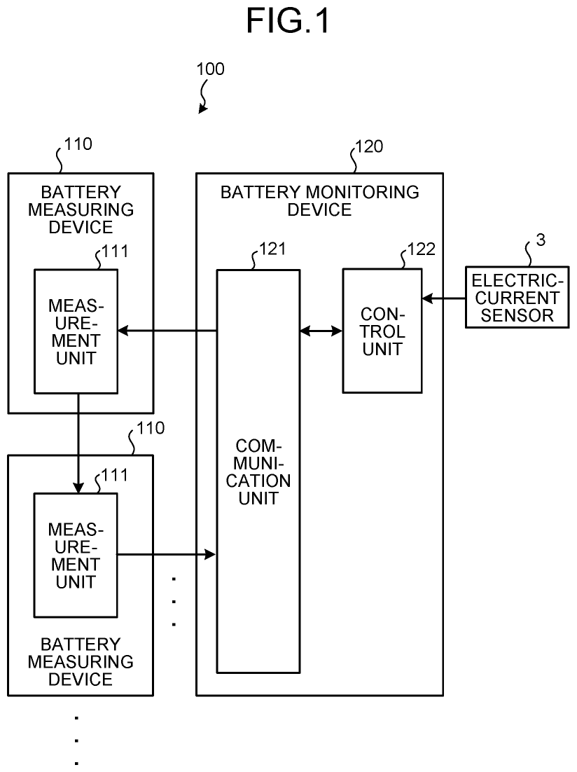

FIG. 1 is a diagram illustrating a battery monitoring system 100 using wired communication. The battery monitoring system 100 is a system that is configured to calculate a cell resistance of a battery by using voltage information on a voltage output from the battery obtained by serially connecting a plurality of batteries and current information on current flowing through the battery, so as to monitor a deteriorated state of the battery on the basis of a resistance value of the cell resistance.

As illustrated in FIG. 1, the battery monitoring system 100 includes a plurality of battery measuring devices 110 and a single battery monitoring device 120, for example. The battery measuring devices 110 are provided for each predetermined number of serially-connected battery cells (namely, stack). Each of the battery measuring devices 110 includes a corresponding measurement unit 111 that is configured to measure voltages of battery cells and further to output voltage information. The measurement units 111 are connected by using harnesses so as to transmit and receive voltage information by using wired communication.

The battery monitoring device 120 includes a communication unit 121 and a control unit 122. The communication unit 121 is configured to be connected to the battery measuring devices 110 by using harnesses, transmit voltage measuring instructions to the battery measuring devices 110 by using wired communication, and receive voltage information on battery cells from the battery measuring devices 110 by using wired communication. The communication unit 121 transmits the received voltage information to the control unit 122 by using wired communication.

The control unit 122 receives current information from an electric-current sensor 3 by using wired communication, which is configured to measure current flowing through batteries. The control unit 122 calculates a cell resistance value of the batteries from synchronized voltage information and current information. In other words, the control unit 122 calculates a cell resistance value at a time point from voltage information and current information that are measured at the same time point. Next, the control unit 122 monitors a deteriorated state of the batteries on the basis of a cell resistance value at each time point.

Specifically, the control unit 122 transmits, to the communication unit 121, an instruction to output a voltage measuring instruction to the battery measuring device 110. In accordance with the instruction transmitted from the control unit 122, the communication unit 121 transmits a voltage measuring instruction to the battery measuring device 110, for example. The battery measuring device 110, which receives the voltage measuring instruction, measures a voltage of a corresponding battery cell, and further transmits voltage information on the measured voltage and the voltage measuring instruction to the adjacent battery measuring device 110.

In a case where receiving a voltage measuring instruction, each of the battery measuring devices 110 measures a voltage of a corresponding battery cell, and further sequentially transmits, to the next battery measuring device 110, a voltage measuring instruction along with voltage information on the measured voltage and voltage information received from the adjacent battery measuring device.

Finally, the battery measuring device 110 having received a voltage measuring instruction transmits, to the battery monitoring device 120, voltage information on voltages that are measured by all of the battery measuring devices 110. As described above, the battery monitoring system 100 executes a series of processes starting from transmission of a voltage measuring instruction up to acquisition of battery information by using wired serial communication.

Herein, all of communication inside the battery monitoring device 120, communication between the battery monitoring device 120 and the battery measuring devices 110, communication between the battery measuring devices 110, and communication between the battery monitoring device 120 and the electric-current sensor 3 are executed by using wired communication. Time intervals needed for communication between devices are decided by a design.

Thus, the battery monitoring device 120 is capable of recognizing, without delay, a time interval from transmission of an instruction for causing the communication unit 121 to transmit a voltage measuring instruction until measurement of voltages by battery measuring devices. Therefore, the battery monitoring device 120 is capable of calculating a cell resistance value based on a current measured at a time point that is the same as a time point when a voltage is measured by each of the battery measuring devices 110, namely, synchronized voltage information and current information.

However, it is necessary that the battery monitoring device 120 and the battery measuring devices 110, and the battery measuring devices 110 are connected by using harnesses, and thus it is difficult to realize a harnessless configuration in the battery monitoring system 100 and further is difficult to realize miniaturization thereof. Thus, in the battery monitoring system according to the embodiments, communication between the battery monitoring device and each of battery measuring devices is executed by using wireless communication so as to realize a harnessless configuration.

### 2. Battery Monitoring System According to First Embodiment

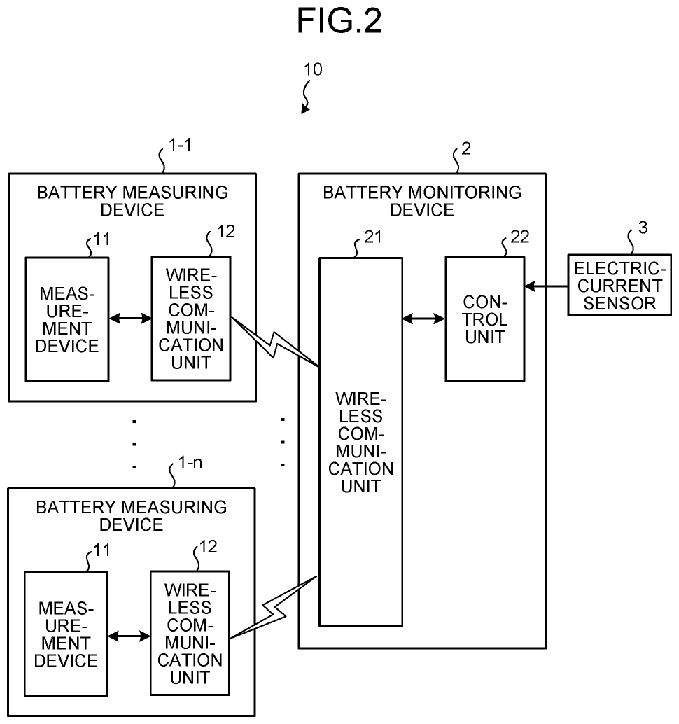

FIG. 2 is a diagram illustrating a battery monitoring system 10 according to a first embodiment. As illustrated in FIG. 2, the battery monitoring system 10 includes a plurality of battery measuring devices 1-1 to 1-n (n is natural number that is equal to or more than two) and a single battery monitoring device 2, for example.

The battery measuring devices 1-1 to 1-n are provided for each of a predetermined number of serially-connected battery cells (namely, stack). Each of the battery measuring devices 1-1 to 1-n includes a measurement unit 11 and a wireless communication unit 12. The measurement unit 11 measures a voltage of each of battery cells so as to generate voltage information.

The wireless communication unit 12 is a communication Integrated Circuit (communication IC) having a communication function using Bluetooth Low Energy (BLE: Registered Trademark), for example. The wireless communication unit 12 executes wireless communication with the battery monitoring device 2 by using BLE communication. The wireless communication unit 12 executes wired communication with the measurement unit 11 by using Serial Peripheral Interface (SPI: Registered Trademark), for example.

The battery monitoring device 2 includes a wireless communication unit 21 and a control unit 22. The wireless communication unit 21 is a communication IC having a BLE communication function, for example. The wireless communication unit 21 executes wireless communication with the wireless communication units 12 of the battery measuring devices 1-1 to 1-n by using BLE communication. The wireless communication unit 21 executes wired communication with the control unit 22 by using SPI communication, for example.

The control unit 22 includes a microcomputer, which includes a Central Processing Unit (CPU), a Read Only Memory (RPM), a Random Access Memory (RAM), and the like; and various circuits. The control unit 22 causes a CPU to execute a program stored in a ROM while using a RAM as a work region so as to control overall operations of the battery monitoring device 2.

For example, the control unit 22 transmits a transmission instruction of a voltage measuring instruction to the wireless communication unit 21, executes a process for acquiring voltage information and current information on a battery, executes a cell-resistance-value calculating process of the battery, and further executes a deterioration determination process of the battery based on a cell resistance value. Note that a part or whole of the control unit 22 may be constituted of hardware such as an Application Specific Integrated Circuit (ASIC) and a Field Programmable Gate Array (FPGA).

The control unit 22 transmits, to the wireless communication unit 21, an instruction to output a voltage measuring instruction to each of the battery measuring devices 1-1 to 1-n by using SPI communication. The wireless communication unit 21 transmits, to each of the battery measuring devices 1-1 to 1-n by using BLE communication, a voltage measuring instruction in accordance with an instruction transmitted from the control unit 22, for example.

The wireless communication unit 12 of each of the battery measuring devices 1-1 to 1-n having received a voltage measuring instruction transmits a voltage measuring instruction to the measurement unit 11 by using SPI communication. The measurement unit 11 having received a voltage measuring instruction measures a voltage of a corresponding battery cell, and further transmits, to the wireless communication unit 12 by using SPI communication, voltage information on the measured voltage. The wireless communication unit 12 transmits the voltage information received from the measurement unit 11 to the battery monitoring device 2 by using BLE communication.

The wireless communication unit 21 of the battery monitoring device 2 transmits, to the control unit 22 by using SPI communication, voltage information received from the battery measuring devices 1-1 to 1-n. On the basis of the received voltage information of the each of the battery cells and current information received from the electric-current sensor 3 by using wired communication, the control unit 22 calculates a cell resistance value of each of the battery cells. On the basis of a cell resistance value of each of the battery cells, the control unit 22 monitors a deteriorated state of a battery.

As described above, in the battery monitoring system 10, the battery monitoring device 2 and each of the battery measuring devices 1-1 to 1-n execute information communication with each other by wireless communication using BLE communication, and thus it is unnecessary to connect the battery monitoring device 2 and each of the battery measuring devices 1-1 to 1-n to each other by using harnesses. In other words, in the battery monitoring system 10, it is possible to realize a harnessless configuration between the battery monitoring device 2 and each of the battery measuring devices 1-1 to 1-n.

In the battery monitoring system 10, an error may occur in a communication timing between the battery monitoring device 2 and each of the battery measuring devices 1-1 to 1-n. Thus, by simply employing a harnessless configuration alone, the battery monitoring device 2 is not capable of recognizing a precise acquisition timing of voltage information obtained by each of the battery measuring devices 1-1 to 1-n. As a result, there presents a case where the battery monitoring device 2 is not capable of acquiring current information of a battery at an acquisition timing that is synchronized with an acquisition timing of voltage information obtained by each of the battery measuring devices 1-1 to 1-n.

Specifically, in a case where being started up, the wireless communication unit 21 of the battery monitoring device 2 executes pairing regarding communication between each of the battery measuring devices 1-1 to 1-n and the wireless communication unit 12. In this case, the control unit 22 is not capable of recognizing a timing (time point) at which pairing is established. Next, the wireless communication unit 21 of the battery monitoring device 2 periodically executes BLE communication with the wireless communication units 12 of the battery measuring devices 1-1 to 1-n with preset predetermined connection intervals.

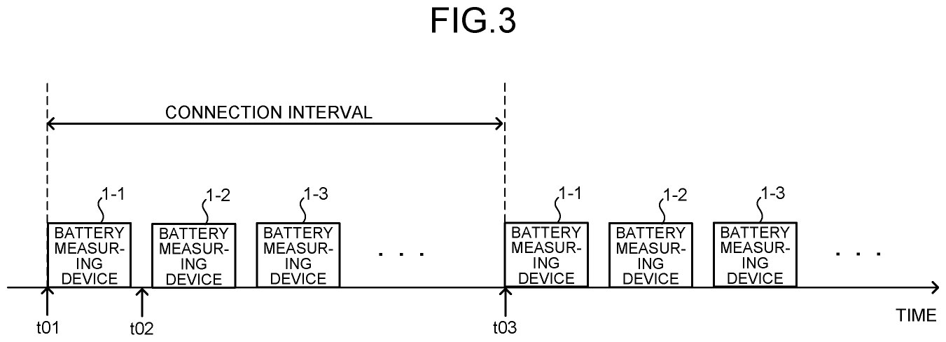

FIG. 3 is a diagram illustrating a connection interval of the wireless communication unit 21 according to the first embodiment. As illustrated in FIG. 3, the wireless communication unit 21 sequentially executes BLE communication with the battery measuring devices 1-1 to 1-n during a time interval of a connection interval.

Thus, for example, in a case where an instruction of a voltage measuring instruction targeting the battery measuring device 1-1 is transmitted, at a time point t01, from the control unit 22 of the battery monitoring device 2 to the wireless communication unit 21, a voltage measuring instruction is transmitted to the battery measuring device 1-1 just thereafter, and a voltage is measured by the battery measuring device 1-1.

Thus, current information on current that is measured at a timing when the control unit 22 transmits a voltage measuring instruction to the wireless communication unit 21, and voltage information on voltage that is measured by the battery measuring device 1-1 become synchronized information. Therefore, the control unit 22 is capable of calculating a precise cell resistance value on the basis of the synchronized current information and voltage information.

However, for example, in a case where an instruction of a voltage measuring instruction targeting the battery measuring device 1-1 is transmitted, at a time point t02, from the control unit 22 to the wireless communication unit 21 of the battery monitoring device 2, the next communicable timing with the battery measuring device 1-1 is a time point t03 from which the next connection interval starts.

Thus, an error may occur in measurement timings of current information on current that is measured at a timing when a voltage measuring instruction is transmitted from the control unit 22 to the wireless communication unit 21 and voltage information on voltage that is measured by the battery measuring device 1-1, and thus a synchronized state is not obtained. Therefore, the control unit 22 is not capable of calculating a precise cell resistance value.

Thus, the battery monitoring system 10 includes the battery measuring devices 1-1 to 1-n and the battery monitoring device 2. Each of the battery measuring devices 1-1 to 1-n detects voltage information on a corresponding battery. For example, the battery monitoring device 2 acquires voltage information from each of the battery measuring devices 1-1 to 1-n by using wireless communication such as BLE communication, and further acquires current information on current flowing through the battery from the electric-current sensor 3.

The battery monitoring device 2 includes the control unit 22 and the wireless communication unit 21 that executes wireless communication with the battery measuring devices 1-1 to 1-n with a predetermined period. The control unit 22 causes the wireless communication unit 21 to output a voltage measuring instruction, and further on the basis of a timing when the wireless communication unit 21 transmits voltage measuring instructions to the battery measuring devices 1-1 to 1-n, acquires current information during a time interval in which the battery measuring devices 1-1 to 1-n acquire voltage information. Next, a monitoring method of a battery to be executed by the battery monitoring system 10 will be explained.

### 3. Battery Monitoring Method According to First Embodiment

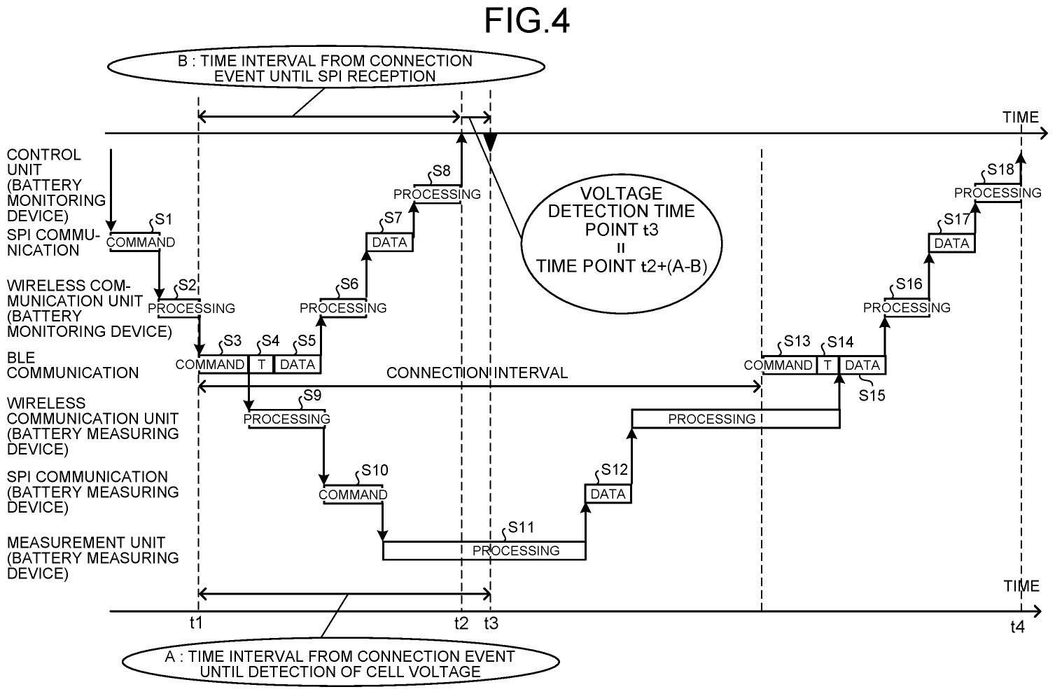

FIG. 4 is a timing diagram illustrating an operation example of the battery monitoring system 10 according to the first embodiment. Herein, communication between a battery monitoring device 1 and the battery measuring devices 1-1 is exemplified.

As illustrated in FIG. 4, in a case where monitoring a battery, the control unit 22 of the battery monitoring device 2 transmits, to the wireless communication unit 21 by using SPI communication, a command including an instruction for outputting voltage measuring instructions to the respective battery measuring devices 1-1 (Step S1).

In a case where receiving the command, the wireless communication unit 21 of the battery monitoring device 2 executes a predetermined process for communicating with the battery measuring devices 1-1, setting of a waiting time interval until the next communication start, and the like (Step S2). Next, at a time point t1 from which the next connection interval starts, the wireless communication unit 21 transmits a command including a voltage measuring instruction to the wireless communication unit 12 of the battery measuring device 1-1 by using BLE communication (Step S3).

Next, in a case where a predetermined communication forbidden time interval T has elapsed (Step S4), the wireless communication unit 21 receives data from the wireless communication unit 12 of the battery measuring device 1-1 by using BLE communication (Step S5). In this case, the wireless communication unit 21 receives, from the battery measuring device 1-1, data in response to the last command that is transmitted before a command transmitted at the time point t1. In a case where the last-transmitted command includes a voltage measuring instruction, the data received in Step S5 includes voltage information during the last connection interval.

The wireless communication unit 21 executes a predetermined process for communicating with the control unit 22, setting of a waiting time interval until the next communication start, and the like (Step S6), and then transmits, to the control unit 22 by using SPI communication, data received from the battery measuring device 1-1 (Step S7). The control unit 22 executes predetermined interrupt handling (Step S8), and reception of data that is transmitted from the wireless communication unit 21 is completed at a time point t2.

On the other hand, in a case where receiving a command including a voltage measuring instruction from the battery monitoring device 2, the wireless communication unit 12 of the battery measuring device 1-1 executes a predetermined process for communicating with the measurement unit 11, setting of a waiting time interval until the next communication start, and the like (Step S9), and further transmits a command to the measurement unit 11 by using SPI communication (Step S10).

In a case where receiving a command including a voltage measuring instruction, at a time point t3, the measurement unit 11 measures a voltage of a battery cell that is a measurement target, and further executes A/D conversion on the measured voltage so as to generate voltage information (Step S11). Next, the measurement unit 11 transmits data including the voltage information to the wireless communication unit 12 by using SPI communication (Step S12).

In a case where it is during the next connection interval, the wireless communication unit 12 of the battery measuring device 1-1 receives a command including the next voltage measuring instruction from the battery monitoring device 2 by using BLE communication. The wireless communication unit 12 executes a predetermined process for communicating with the wireless communication unit 21 of the battery monitoring device 2, setting of a waiting time interval until the next communication start, and the like (Step S13), and further in a case where the predetermined communication forbidden time interval T has elapsed (Step S14), transmits data including the present voltage information to the battery monitoring device 2 by using BLE communication (Step S15).

In a case where receiving the data, the wireless communication unit 21 of the battery monitoring device 2 executes a predetermined process for communicating with the control unit 22, setting of a waiting time interval until the next communication start, and the like (Step S16), and further transmits data including the present voltage information to the control unit 22 by using SPI communication (Step S17). After executing predetermined interrupt handling (Step S18), the control unit 22 completes, at a time point t4, reception of data including the voltage information transmitted from the wireless communication unit 21.

In the above-mentioned series of operations, the control unit 22 is capable of recognizing a timing of transmission of a command including a voltage measuring instruction to the wireless communication unit 21 of the battery monitoring device 2; however, as described above, cannot recognize the time point t1 of a timing at which the wireless communication unit 21 transmits a command to the battery measuring device 1-1. Note that the control unit 22 is not capable of recognizing the time point t2 of a timing at which receiving, from the wireless communication unit 21, reception data transmitted from the battery measuring device 1-1 of the battery monitoring device 2.

A first time interval A is predetermined by a design, which is from a time when the wireless communication unit 21 of the battery monitoring device 2 transmits a command including a voltage measuring instruction to the battery measuring device 1-1 at the time point t1 until a time when the measurement unit 11 of the battery measuring device 1-1 measures a voltage of a battery cell at the time point t3.

A second time interval B is predetermined by a design, which is from a time when the wireless communication unit 21 of the battery monitoring device 2 transmits a command including a voltage measuring instruction to the battery measuring device 1-1 at the time point t1 until the time point t2 when a process for transmitting reception data transmitted from the battery measuring device 1-1 to the control unit 22 is completed.

Thus, the control unit 22 acquires, from the electric-current sensor 3, current information on current measured by the electric-current sensor 3 at the time point t3 obtained by adding a time interval, which is obtained by subtracting the second time interval B from the first time interval A, to the time point t2 when receiving reception data transmitted from the battery measuring device 1-1.

The control unit 22 stores therein current information acquired at the time point t3, and associates therewith voltage information acquired by the battery measuring device 1-1 at the time point t3, in other words, voltage information that is received at the time point t4. Next, the control unit 22 calculates a cell resistance value from the associated current information and the voltage information.

As described above, the control unit 22 acquires current information during a time interval in which the battery measuring device 1-1 acquires voltage information, which executes determination by using, as a reference, a timing when the wireless communication unit 21 transmits a voltage measuring instruction to the battery measuring device 1-1.

Specifically, the control unit 22 acquires current information after a predetermined time interval from a reception timing at which receiving, from the wireless communication unit 21, reception data transmitted from the battery measuring device 1-1 at a cycle in which the wireless communication unit 21 transmits a voltage measuring instruction to the battery measuring devices 1-1.

In this case, the predetermined time interval is a time interval obtained by subtracting a predetermined second time interval, which is from a time when the wireless communication unit 21 transmits a voltage measuring instruction to the battery measuring devices 1-1 until the control unit 22 receives reception data, from a predetermined first time interval from a time when the wireless communication unit 21 transmits a voltage measuring instruction to the battery measuring device 1-1 until the battery measuring device 1-1 acquires voltage information.

Thus, the control unit 22 acquires current information on current that is measured by the electric-current sensor 3 at the same time point as the time point t3 when a voltage is measured by the battery measuring device 1-1. The control unit 22 is capable of calculating a precise cell resistance of a battery cell at the time point t3 on the basis of voltage information on a voltage that is measured by the battery measuring device 1-1 at the time point t3, which is to be acquired at the time point t4, current information on a current that is measured by an electric-current sensor at the time point t3. Therefore, the battery monitoring device 2 is capable of appropriately monitoring a deteriorated state of a battery.

### 4. Process to be Executed by Control Unit According to First Embodiment

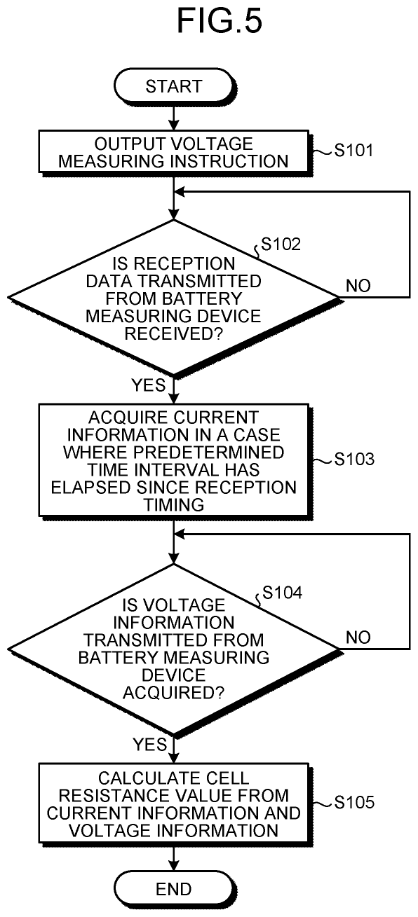

Next, with reference to FIG. 5, a process to be executed by the control unit 22 of the battery monitoring device 2 according to the first embodiment will be explained. FIG. 5 is a flowchart illustrating one example of a process executed by the control unit 22 according to the first embodiment.

Herein, a case will be explained in which the battery monitoring device 2 executes a process for calculating a cell resistance of a battery cell whose voltage is measured by the battery measuring device 1-1; however, the battery monitoring device 2 executes similar or the same process on the battery measuring devices 1-2 to 1-n other than the battery measuring device 1-1. Thus, explanation is omitted regarding processes that are to be executed on battery measuring devices 2-1 to 1-n by the battery monitoring device 2.

As illustrated in FIG. 5, the control unit 22 outputs a voltage measuring instruction to the wireless communication unit 21 of the battery monitoring device 2 (Step S101). Next, the control unit 22 determines whether or not receiving reception data transmitted from the battery measuring device 1-1 (Step S102).

In a case where determining that reception data is not received from the battery measuring device 1-1 (Step S102: No), the control unit 22 repeats the determination process in Step S102 until receiving reception data. In a case where determining that receiving reception data transmitted from the battery measuring device 1-1 (Step S102: Yes), the control unit 22 acquires current information in a case where a predetermined time interval has elapsed since the reception timing (Step S103).

Specifically, at a time point obtained by adding a time interval, which is obtained by subtracting the second time interval B from the above-mentioned first time interval A, to a time point at which receiving reception data transmitted from the battery measuring device 1-1, the control unit 22 acquires, from the electric-current sensor 3, current information on current that is measured by the electric-current sensor 3, and further stores therein the acquired information. The above-mentioned current information corresponds to the current information that is acquired at the time point t3, which is illustrated in FIG. 4.

Next, the control unit 22 determines whether or not voltage information is acquired from the battery measuring device 1-1 with respect to a voltage measuring instruction at the present cycle, which is output in Step S101 (Step S104). The above-mentioned voltage information is voltage information that is acquired at the time point t4 illustrated in FIG. 4. In a case where determining that not acquiring voltage information (Step S104: No), the control unit 22 repeats the determination process of Step S104 until acquiring the voltage information. In a case where it is determined to be “No” in Step S104, actually, the control unit 22 executes various processes such as transmission of the next instruction, description thereof is omitted for convenience of explanation.

In a case where determining that voltage information is acquired from the battery measuring device 1-1 (Step S104: Yes), the control unit 22 calculates a cell resistance value from the acquired current information and the voltage information (Step S105), and further ends the processing. The control unit 22 repeats the processes of Steps S101 to S105, and further monitors deterioration in a battery cell whose voltage is measured by the battery measuring device 1-1 on the basis of cell resistance values that are sequentially calculated.

### 5. Battery Monitoring System According to Second Embodiment

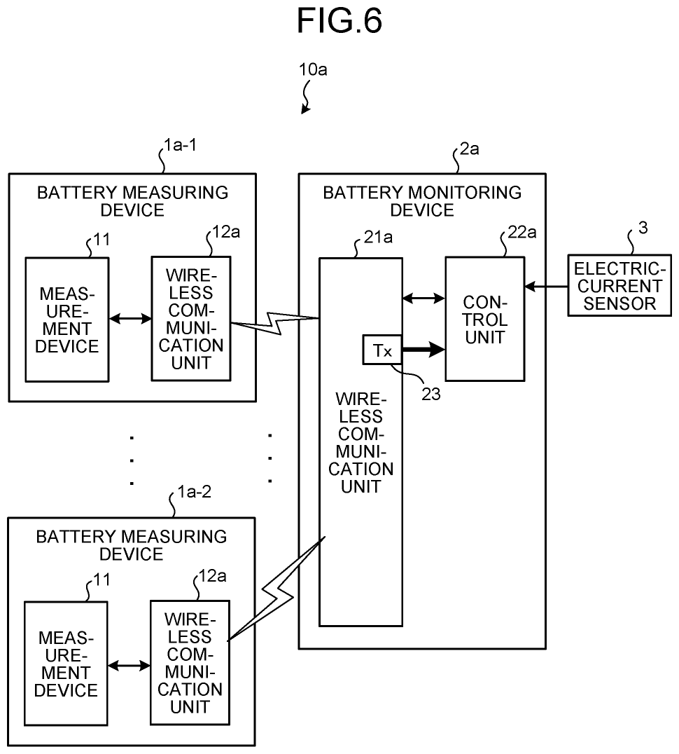

FIG. 6 is a diagram illustrating a battery monitoring system 10a according to a second embodiment. As illustrated in FIG. 6, the battery monitoring system 10a includes a plurality of battery measuring devices 1a-1 to 1a-n (n is natural number that is equal to or more than two) and a battery monitoring device 2a.

In the battery measuring devices 1a-1 to 1a-n, operations of wireless communication units 12a are different from those of the wireless communication units 12 according to the first embodiment. The battery monitoring device 2a is different from the battery monitoring device 2 according to the first embodiment in that a wireless communication unit 21a has a configuration including a Tx terminal 23 and in operations of a control unit 22a.

The wireless communication unit 21a of the battery monitoring device 2a outputs, from the Tx terminal 23 to the control unit 22a, a communication starting signal indicating a communication start at a timing of transmission of a voltage measuring instruction to the battery measuring devices 1a-1 to 1a-n.

In a case where receiving a voltage measuring instruction, the battery measuring devices 1a-1 to 1a-n transmit, to the wireless communication unit 21a of the battery monitoring device 2a, first time information that indicates a detection time of voltage information with reference to a timing at which a voltage measuring instruction is transmitted, and voltage information detected at the detection time interval.

The control unit 22a periodically detects second time information with reference to an input timing of a communication starting signal, and current information, and further stores therein the detected information so as to acquire current information in synchronization with the voltage information on the basis of the first time information and the second time information. Next, a monitoring method of a battery to be executed by the battery monitoring system 10a will be explained.

### 6. Battery Monitoring Method According to Second Embodiment

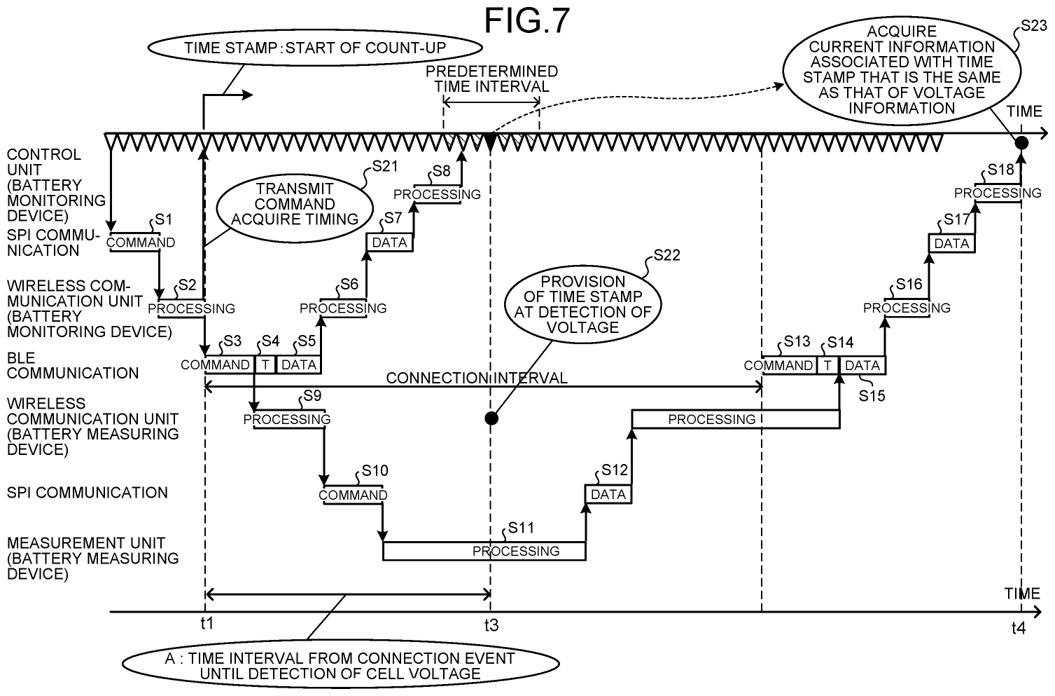

FIG. 7 is a timing diagram illustrating an operation example of the battery monitoring system 10 according to the second embodiment. Herein, communication performed between the battery monitoring device 1 and the battery measuring device 1a-1 is exemplified.

As illustrated in FIG. 7, a transmission/reception timing of data between the battery monitoring device 2a and the battery measuring device 1a-1 is the same as the transmission/reception timing illustrated in FIG. 4, and an operation executed in the battery monitoring device 2a and the battery measuring device 1a-1 is different from that according to the first embodiment. Herein, an operation executed in the battery monitoring device 2a and the battery measuring device 1a-1 will be explained, which is different from that according to the first embodiment.

As illustrated in FIG. 7, at a timing of transmission of a command including a voltage measuring instruction to the battery measuring device 1a-1 at the time point t1, the wireless communication unit 21a of the battery monitoring device 2a outputs, to the control unit 22a from the Tx terminal 23, a communication starting signal indicating a communication start with the battery measuring device 1a-1 (Step S21). Thus, the wireless communication unit 21a acquires a command transmission timing at the time point t1.

In a case where receiving a voltage measuring instruction, the measurement unit 11 of the battery measuring device 1a-1 measures a voltage of a battery cell at the time point t3 so as to generate voltage information, and further transmits the generated information to a wireless communication unit 12a of the battery measuring device 1a-1. The wireless communication unit 12a provides, to the voltage information, first time information (time stamp of time point at voltage detection) indicating the time point t3 that is a detection time of voltage information with reference to the time point t1 that is a timing when a voltage measuring instruction is transmitted (Step S22).

The wireless communication unit 12a transmits, to the wireless communication unit 21a of the battery monitoring device 2a, first time information and voltage information that is detected during a detection time interval. Next, the control unit 22a of the battery monitoring device 2a acquires, at the time point t4, the voltage information to which first time information is provided.

On the other hand, the control unit 22a of the battery monitoring device 2a periodically detects second time information and current information with reference to the time point t1 that is an input timing of a communication starting signal, and further stores therein the detected information. In other words, at each of timings indicated by a plurality of triangles illustrated in FIG. 7, the control unit 22a acquires current information at a corresponding time point, and further sequentially stores therein the acquired information in association with a counted-up time stamp at the time point.

Next, in a case where acquiring, at the time point t4 from the battery measuring devices 1a-1, voltage information to which a time stamp is provided, the control unit 22a acquires current information synchronized with the voltage information on the basis of the first time information and the second time information.

Specifically, the control unit 22a acquires, from among pieces of stored current information, current information associated with a time stamp that is the same as the time point t3, which is a time stamp provided to the voltage information, or a time stamp that is the closest to the time point t3 (Step S23). Thus, the control unit 22a is capable of acquiring current information and voltage information that are synchronized with each other and have the same measurement time point. Therefore, the battery monitoring device 2 is capable of calculating a precise cell resistance value of a battery cell by using the synchronized current information and voltage information, so that it is possible to appropriately monitor a deteriorated state of a battery.

Herein, a case is explained in which the control unit 22a periodically and continuously acquires current information; however, this is merely one example. The control unit 22a is capable of estimating a rough predetermined time interval during which a voltage is measured by the battery measuring device 1a-1 from the time point t1, which is an input timing of a communication starting signal, on the basis of an information processing ability of the battery measuring device 1a-1.

Therefore, the control unit 22a may be configured to periodically detect the current information and the second time information during a predetermined time interval (predetermined time interval before and after time point t3, which includes time point t3 illustrated in FIG. 7) before and after a time point at which the battery measuring device 1a-1 is supposed to acquire the voltage information.

Thus, the control unit 22a is capable of largely reducing the number of processing times for acquiring current information and an information amount of current information to be stored. In this case, for example, a case may occur in which a time point corresponding to first time information provided to the voltage information is out of a predetermined time interval that is supposed by the control unit 22a, due to a failure in the battery measuring device 1a-1 or the like.

Thus, in a case where a detection time of voltage information indicated by the first time information is separated from supposed detection time by equal to or more than a predetermined time interval, the control unit 22a determines that an abnormality occurs in the battery measuring device 1a-1.

Thus, the battery monitoring device 2a is capable of detecting an abnormality in the battery measuring device 1a-1 in addition to monitoring deterioration in a battery.

### 7. Process to be Executed by Control Unit According to Second Embodiment

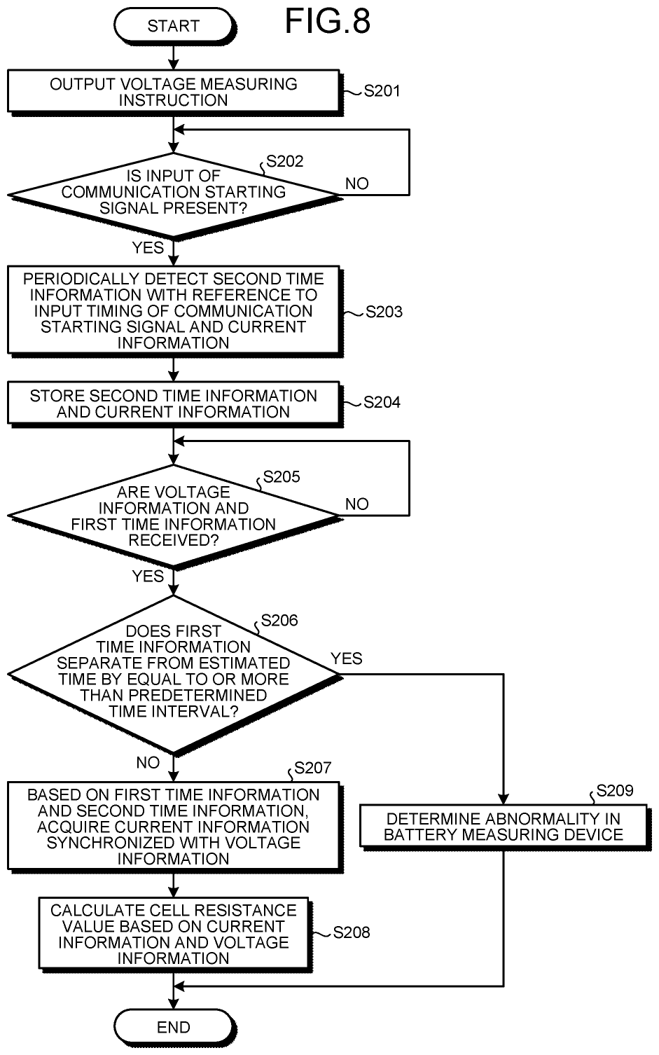

With reference to FIG. 8, a process to be executed by the control unit 22a of the battery monitoring device 2a according to the second embodiment will be explained. FIG. 8 is a flowchart illustrating one example of a process executed by the control unit 22a according to the second embodiment.

Herein, a process will be explained in which the battery monitoring device 2a calculates a cell resistance of a battery cell whose voltage is measured by the battery measuring device 1a-1, the battery monitoring device 2a executes the same or similar process on the other battery measuring devices 1a-2 to 1a-n. Thus, explanation of the process to be executed on the battery measuring devices 1a-2 to 1-n by the battery monitoring device 2 is omitted.

As illustrated in FIG. 8, the control unit 22a outputs a voltage measuring instruction (Step S201), and further determines whether or not there presents an input of a communication starting signal (Step S202). In a case where determining that there presents no input of a communication starting signal (Step S202: No), the control unit 22a repeats the determination process in Step S202 until a communication starting signal is input.

In a case where determining that there presents an input of a communication starting signal (Step S202: Yes), the control unit 22a periodically detects second time information with reference to an input timing of an input of a communication starting signal and current information (Step S203). The control unit 22a stores therein the second time information and the current information in association with each other (Step S204).

Next, the control unit 22a determines whether or not receiving voltage information and first time information corresponding to a voltage measuring instruction in the present cycle which is output from the battery measuring device 1a-1 in Step S201 (Step S205). In a case where determining that not receiving voltage information and first time information (Step S205: No), the control unit 22a repeats the process in Step S205 until receiving the voltage information and the first time information. Note that in a case where determination result is “No” in Step S205, the control unit 22a actually executes various processes such as transmission of the next instruction; however, explanation thereof is omitted for convenience of explanation.

In a case where determining that voltage information and first time information are received (Step S205: Yes), the control unit 22a determines whether or not the first time information is separated from an estimated time by equal to or more than a predetermined time interval (Step S206).

In a case where determining that first time information is not separated from an estimated time by equal to or more than the predetermined time interval (Step S206: No), the control unit 22a acquires current information synchronized with the voltage information from stored current information on the basis of the first time information and the second time information (Step S207).

Next, the control unit 22a calculates a cell resistance value based on the acquired current information and the voltage information (Step S208), and further ends the processing. The control unit 22a repeats the processes in Steps S201 to S208, and further monitors deterioration in a battery cell whose voltage is measured by the battery measuring device 1a-1 on the basis of a sequentially calculated cell resistance value.

In a case where determining that first time information is separated from an estimated time by equal to or more than the predetermined time interval (Step S206: Yes), the control unit 22a determines an abnormality in the battery measuring device 1a-1 (Step S209), and further ends the processing.

### 8. Process to be Executed by Battery Measuring Device According to Second Embodiment

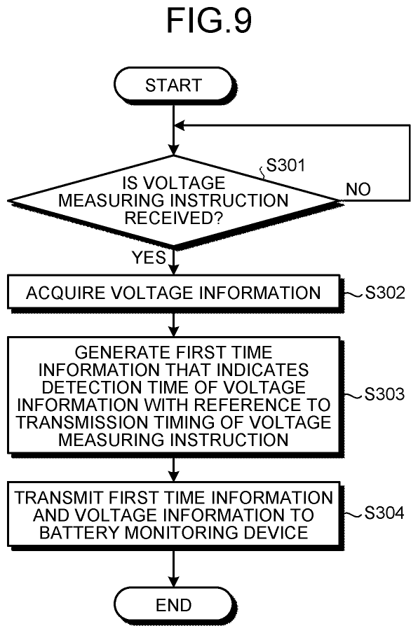

Next, with reference to FIG. 9, a process to be executed by the battery measuring device 1a-1 according to the second embodiment will be explained. FIG. 9 is a flowchart illustrating one example of a process executed by the battery measuring device 1a-1 according to the second embodiment.

As illustrated in FIG. 9, the battery measuring device 1a-1 determines whether or not receiving a voltage measuring instruction from the battery monitoring device 2a (Step S301). In a case where determining that not receiving a voltage measuring instruction (Step S301: No), the battery measuring device 1a-1 repeats the determination process in Step S301 until receiving a voltage measuring instruction.

In a case where determining that a voltage measuring instruction is received (Step S301: Yes), the battery measuring device 1a-1 acquires voltage information (Step S302). Subsequently, the battery measuring device 1a-1 generates first time information that indicates a detection time of the voltage information with reference to a transmission timing of a voltage measuring instruction (Step S303).

The battery measuring device 1a-1 regards a reception timing, at which reception of a voltage measuring instruction is determined in Step S301, as a transmission timing of a voltage measuring instruction. Note that the wireless communication unit 21a may transmit a time stamp indicating a transmission time point along with a voltage measuring instruction, and in this case, a time stamp indicating the transmission time point becomes a transmission timing of the voltage measuring instruction.

The battery measuring device 1a-1 transmits first time information and voltage information in association with each other to the battery monitoring device 2a (Step S304), and further ends the processing. Next, the battery measuring device 1a-1 starts again the processes from Step S301.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

### REFERENCE SIGNS LIST

10, 10a Battery monitoring system
1-1 to 1-n, 1a-1 to 1a-n Battery measuring device
11 Measurement unit
12, 12a Wireless communication unit
2, 2a Battery monitoring device
21, 21a Wireless communication unit
22, 22a Control unit
3 Electric-current sensor

1. A battery monitoring system comprising:
battery measuring devices each of which detects voltage information on a corresponding battery; and
a battery monitoring device, wherein
the battery monitoring device includes:
a communication Integrated Circuit (communication IC) that executes wireless communication with the battery measuring devices with a predetermined period, and
a controller for acquiring the voltage information from each of the battery measuring devices by using wireless communication and acquiring current information on current flowing through the corresponding battery from an electric-current sensor, and
the controller is configured to:
cause the communication IC to output a voltage measuring instruction; and
based on a timing at which the communication IC transmits the voltage measuring instruction to the battery measuring device, acquire the current information during a time interval in which the battery measuring device acquires voltage information.

2. The battery monitoring system according to claim 1, wherein
the controller is further configured to:
acquire the current information during a time interval in which the battery measuring device to be determined acquires voltage information with reference to a timing at which the communication IC transmits the voltage measuring instruction to the battery measuring device.

3. The battery monitoring system according to claim 2, wherein
the controller is further configured to:
acquire the current information after a predetermined time interval from a reception timing at which receiving, from the communication IC, reception data transmitted from the battery measuring device at a cycle in which the communication IC transmits the voltage measuring instruction to the battery measuring devices.

4. The battery monitoring system according to claim 3, wherein
the predetermined time interval is a time interval obtained by subtracting a predetermined second time interval, which is from a time when the communication IC transmits the voltage measuring instruction to the battery measuring devices until the controller receives the reception data, from a predetermined first time interval from a time when the communication IC transmits the voltage measuring instruction to the battery measuring device until the battery measuring device acquires voltage information.

5. The battery monitoring system according to claim 1, wherein
the communication IC is configured to:
output, to the controller at a timing of transmission of the voltage measuring instruction, a communication starting signal that indicates a communication start,
the battery measuring device is configured to:
in a case where receiving the voltage measuring instruction, transmit, to the communication IC, first time information indicating a detection time of the voltage information with reference to a timing when the voltage measuring instruction is transmitted and the voltage information detected at the detection time, and
the controller is further configured to:
periodically detect and store second time information with reference to an input timing of the communication starting signal and the current information; and
based on the first time information and the second time information, acquire the current information that is synchronized with the voltage information.

6. The battery monitoring system according to claim 5, wherein
the controller is further configured to:
periodically detect the current information and the second time information during a predetermined time interval before and after a time point at which the battery measuring device is supposed to acquire voltage information.

7. The battery monitoring system according to claim 5, wherein
the controller is further configured to:
in a case where a detection time of the voltage information indicated by the first time information is separated from a supposed detection time by equal to or more than a predetermined time interval, determine that an abnormality occurs in the battery measuring device.

8. A battery monitoring device comprising:
a communication IC that executes wireless communication with battery measuring devices each detecting voltage information of a corresponding battery with a predetermined period, and
a controller that is configured to:
acquire the voltage information that is received by the communication IC from the battery measuring device by using wireless communication; and
acquire current information on current flowing through the battery from an electric-current sensor, wherein
the controller is further configured to:
cause the communication IC to output a voltage measuring instruction; and
based on a timing at which the communication IC transmits the voltage measuring instruction to the battery measuring device, acquire the current information during a time interval in which the battery measuring device acquires voltage information.

9. (canceled)

10. A battery monitoring system comprising:
a voltage monitoring device detecting a voltage on a battery;
a controller outputting a voltage measuring instruction to the voltage monitoring device via a communication IC to receive a voltage via wireless communication, wherein
in response to the voltage measuring instruction output from the communication IC, the controller receives a current flowing through the battery from an electric-current sensor during a time interval in which the voltage monitoring device acquires the voltage.
